(19) United States
(12) Patent Application Publication
(10) Pub. No.: US 2003/0025201 A1
(43) Pub. Date: Feb. 6, 2003

(54) Integrated circuit chip with little possibility of becoming damaged and structure for mounting the same

(76) Inventor: Hiroshi Harada, Fukushima-ken (JP)

Correspondence Address: BRINKS HOFER GILSON & LIONE, P.O. BOX 10395, CHICAGO, IL, 60611, US

(21) Appl. No.: 10/191,989

(22) Filed: Jul. 9, 2002

(30) Foreign Application Priority Data
Jul. 13, 2001 (JP) 2001-214188

(51) Int. Cl. H01L 23/48

(52) U.S. Cl. 257/734

(57) ABSTRACT

An integrated circuit chip in which enlarged lands are provided at four corners of the bottom surface of the integrated circuit chip, and a large amount of cream solder adheres to the enlarged lands, so that the four corners of the integrated circuit chip are firmly soldered to a mother board, as a result of which, even if an external force is applied when, for example, the integrated circuit chip and the mother board are subjected to shock or are twisted, the relative position between them does not easily change. In addition, even if a portion between the integrated circuit chip and the mother board is not reinforced by injecting an insulating adhesive therebetween, it is possible to provide a highly reliable integrated circuit chip, to increase working efficiency during the mounting process of the IC chip, and to reduce the possibility of solder connection portions becoming damaged due to changes in environmental temperature.

### BACKGROUND OF THE INVENTION

1. Field of the Invention

The present invention relates to an integrated circuit (IC) chip, such as a BGA (ball grid array) type IC chip and a BCC (bump chip carrier) type IC chip, which includes a semiconductor device and which has a group of external connection lands disposed in a grid-like arrangement at the bottom surface of the IC chip; and a structure for mounting this type of IC chip to a mother board.

2. Description of the Related Art

In recent years, production of smaller and thinner electronic devices has caused electronic parts of, for example, an IC chip to be mounted with increasing density. As IC chips suitable for such high-density mounting, there have been developed a BGA-type IC chip formed by adhering solder balls to a group of external connection lands that are disposed in a grid-like arrangement at the bottom surface of the IC chip, and a BCC-type IC chip formed by disposing downwardly protruding conductor terminals in a grid-like arrangement and forming external connection lands on the bottom surfaces of the corresponding conductor terminals by plating. Such IC chips are widely used.

FIG. 6 is a schematic bottom view of an example of a related BGA-type IC chip, and FIG. 7 is a sectional view of a main portion of a structure in which the IC chip is mounted to a mother board. As shown in FIGS. 6 and 7, a BGA-type IC chip 1 includes an interposer substrate 3 having a semiconductor device 2 mounted thereto, a plurality of external connection lands 4 disposed in a grid-like arrangement on the bottom surface of the interposer substrate 3, a plurality of bonding wires 5 which electrically connect the semiconductor device 2 and each of the external connection lands 4, mold resin 6 which, on the interposer substrate 3, provides a seal for the semiconductor device 2 and each of the bonding wires 5, solder balls 7 which are adhered to the corresponding external connection lands 4 and which protrude downward from the bottom surface of the interposer substrate 3, and solder resist 8 which fills the area between adjacent external connection lands 4 at the bottom surface of the interposer substrate 3. When mounting the IC chip 1 to a mother board 20, after printing cream solder onto connection lands 21 that are provided at the mother board 20 in an arrangement corresponding to that of the group of external connection lands 4, the solder balls 7 are placed on the cream solder and the resulting structure is heated at, for example, a reflow furnace in order to electrically and mechanically connect the external connection lands 4 and the corresponding connection lands 21 through molten cream solder 22 and the solder balls 7. Ordinarily, thereafter, in order to provide mechanical strength, as shown in FIG. 7, the IC chip 1 and the mother board 20 are bonded together using an insulating adhesive 30, such as an epoxy adhesive. Since, in the IC chip 1, the solder resist 8 is provided between adjacent external connection lands 4, there is little possibility of a short circuit occurring between adjacent solder balls 7 when the solder balls 7 are fused.

On the other hand, a BCC-type IC chip is formed by forming a group of conductor terminals that are disposed in a grid-like arrangement by etching a base metal. Conventionally, as shown in FIG. 8 (which is a schematic bottom view), after removing the center portion of the bottom surface of an IC chip 10, a group of conductor terminals 11 is disposed on the IC chip 10 so that each conductor terminal 11 protrudes downward. Within mold resin 12, each conductor terminal 11 is connected to a semiconductor device 13 through a bonding wire (not shown). By, for example, gold (Au) plating, external connection lands 14 are formed at the bottom surfaces of the corresponding conductor terminals 11 protruding from the mold resin 12. Therefore, when the IC chip 10 of this type is mounted, by placing the bottom surfaces of the conductor terminals 11 (the external connection lands 14) onto cream solder that has been printed on a group of connection lands on a mother board and heating the resulting structure at, for example, a reflow furnace, the external connection lands 14 and the corresponding connection lands are soldered. Ordinarily, after this, an insulating adhesive like that mentioned above is injected between the IC chip 10 and the mother board in order to provide mechanical strength. Since, in the BCC-type IC chip 10, recesses 15 are formed between corresponding adjacent external connection lands 14, it is possible to prevent a short circuit from occurring when the cream solder is fused, even if solder resist is not provided.

In the above-described related BGA-type IC chip 1 and BCC-type IC chip 10, mechanical strength is provided by injecting the insulating adhesive 30 between the mother board 20 and the IC chip 1 and between the mother board 20 and the IC chip 10 during the mounting process of the IC chips 1 and 10. This is due to the following reason. Here, the solder adherence amount is small because the area of each of the external connection lands 4 and 14 is very small. Therefore, when an external force is applied to products incorporating the IC chip 1 or the IC chip 10 when, for example, they are subjected to shock or are twisted, the portions of the IC chips 1 and 10 and the corresponding mother boards 20 that are connected with solder (solder connection portions) break, so that electrical conduction failure tends to occur when the portions between the IC chips 1 and 10 and the corresponding mother boards 20 are not reinforced with the insulating adhesive 30.

When the step of injecting the insulating adhesive 30 is added to the mounting process of the IC chips 1 and 10 to the corresponding mother boards 20, however, the mounting process becomes complicated, thereby reducing working efficiency during the mounting process. In addition, due to differences in the thermal expansion coefficients of the IC chips 1 and 10 and the mother boards 20 with respect to the thermal expansion coefficient of the insulating adhesive 30, the solder connection portions, embedded in the adhesive 30, tend to be subjected to shearing force when the temperature is high or low. Therefore, electrical conduction failure may occur due to cracks that are formed in the solder connection portions by changes in environmental temperature.

### SUMMARY OF THE INVENTION

The present invention has been achieved in view of the above-described related art problems. It is a first object of the present invention to provide an IC chip, such as a BGA-type IC chip or a BCC-type IC chip, which can be efficiently mounted without any reinforcement with an insulating adhesive and whose portions that are connected to a mother board using solder have little possibility of becoming damaged due to external forces or environmental temperature. It is a second object of the present invention to provide a structure for mounting an IC chip, such as a BGA-type IC chip or a BCC-type IC chip, which makes it possible to efficiently mount the IC chip without any reinforcement with an insulating adhesive, wherein portions of the IC chip that are connected to a mother board using solder have little possibility of becoming damaged due to external forces or environmental temperature.

To achieve the aforementioned first object, there is provided an integrated circuit chip including a semiconductor device and a bonding wire that are subjected to resin molding, and a plurality of external connection lands, connected to the semiconductor device through the bonding wire, that are disposed at a bottom side of the integrated circuit chip and that are soldered and mounted to a group of connection lands provided at a mother board. In the integrated circuit chip, of the plurality of external connection lands, at least the external connection lands that are disposed at four corners of the bottom surface of the integrated circuit chip are formed as enlarged lands that have areas that are larger than areas of the external connection lands that are disposed at other locations.

In this way, when enlarged lands are provided at four corners of the bottom surface of the IC chip, and a large amount of solder adheres to these enlarged lands, the IC chip is firmly soldered to the mother board at the four corners. Therefore, even if an external force is applied when the IC chip and the mother board are subjected to shock or are twisted, the relative position between the IC chip and the mother board does not easily change, so that the portions of the IC chip connected to the mother board by solder (solder connection portions) do not easily get damaged, thereby providing a highly reliable IC chip. In addition, since it is not necessary to inject an insulating adhesive between the IC chip and the mother board in order to reinforce the portion between the IC chip and the mother board, working efficiency during the mounting process of the IC chip is greatly increased, and the possibility of the solder connection portions becoming damaged due to changes in environmental temperature is reduced. Empty spaces whose distances to adjacent lands do not need to be decreased even if the external connection lands are enlarged exist at, for example, the four corners of the bottom surface of the IC chip. Therefore, enlarged lands which do not induce a short circuit can be easily formed by using these empty spaces.

For example, in the case where the IC chip is a BGA-type IC chip whose solder balls are affixed to a plurality of external connection lands disposed on the bottom surface of an interposer substrate, by causing the enlarged lands to be exposed at the outer sides of the corresponding solder balls, the amount of solder that adheres to the enlarged lands can be made larger than the amount of solder that adheres to the other external connection lands during the mounting process of the IC chip.

In such a structure, when a portion of solder resist that is provided between adjacent external connection lands on the bottom surface of the interposer substrate is placed upon locations on the enlarged lands that surround the corresponding solder balls, the positions of the solder balls are restricted by the solder resist, so that shifts in the positions of the solder balls do not occur, thereby making this structure a desirable one.

On the other hand, in the case where the IC chip is a BCC-type IC chip including a plurality of conductor terminals which are connected to a bonding wire and which have outwardly protruding portions, and having external connection lands formed on the bottom surfaces of the corresponding protruding portions thereof by plating, by causing those conductor terminals corresponding to the enlarged lands to be formed with larger diameters than the other conductor terminals, it is possible to cause the amount of solder that adheres to the enlarged lands to be larger than the amount of solder that adheres to the other external connection lands during the mounting process.

To achieve the second object, there is provided a structure for mounting an integrated circuit chip, in which, when the integrated circuit chip is mounted to a mother board, a group of external connection lands and a group of connection lands are soldered with cream solder, with the integrated circuit chip comprising a semiconductor device and a bonding wire that are subjected to resin molding and the plurality of external connection lands, connected to the semiconductor device through the bonding wire, that are disposed at a bottom surface of the integrated circuit chip, and with the mother board having the group of connection lands disposed in an arrangement corresponding to that of the external connection lands. In the structure for mounting an integrated circuit chip, of the external connection lands of the integrated circuit chip, at least the external connection lands disposed at four corners of the bottom surface of the integrated circuit chip are formed as enlarged lands that have areas that are larger than areas of the external connection lands disposed at other locations, and, of the connection lands disposed at the mother board, the connection lands that are soldered to the enlarged lands are formed with areas that are equal to the areas of the enlarged lands, so that an amount of cream solder that adheres to the enlarged lands is greater than an amount of cream solder that adheres to the other external connection lands during the mounting process.

In this way, when the external connection lands that are positioned at the four corners of the bottom surface of the IC chip, and the mother-board-side connection lands which oppose and which are soldered to these external connection lands are made larger than the other lands, and when the adhesion amount of cream solder applied between these lands is increased, the four corners of the IC chip are firmly soldered to the mother board. Therefore, even if an external force is exerted, the relative position between the IC chip and the mother board does not easily change, so that the solder connection portions are formed into more reliable connection portions. In addition, since it is not necessary to reinforce the portion between the IC chip and the mother board using an insulating adhesive, working efficiency during the mounting process of the IC chip is increased.

### BRIEF DESCRIPTION OF THE DRAWINGS

FIG. 1 is a sectional view of the main portion of a BGA-type IC chip of an embodiment of the present invention.

FIG. 2 is a schematic bottom view of the IC chip shown in FIG. 1.

FIG. 3 is a schematic side view showing a state in which the IC chip shown in FIG. 1 is mounted to a mother board.

FIG. 4 is an enlarged view of the portion within IV in FIG. 3.

FIG. 5 is a sectional view of the main portion of a BCC-type IC chip of another embodiment of the present invention.

FIG. 6 is a schematic bottom view of a related BGA-type IC chip.

FIG. 7 is a sectional view of the main portion of a structure where the IC chip shown in FIG. 6 is mounted to a mother board.

FIG. 8 is a schematic bottom view of a related BCC-type IC chip.

### DESCRIPTION OF THE PREFERRED EMBODIMENTS

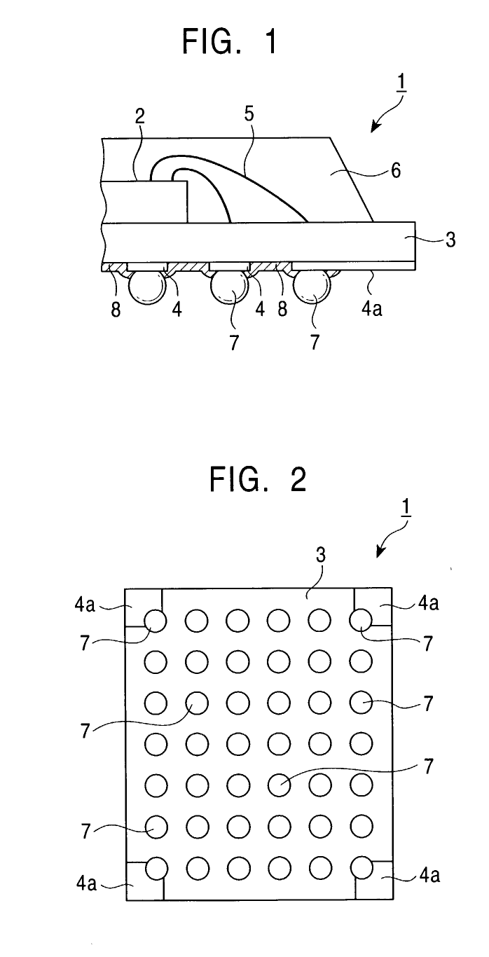

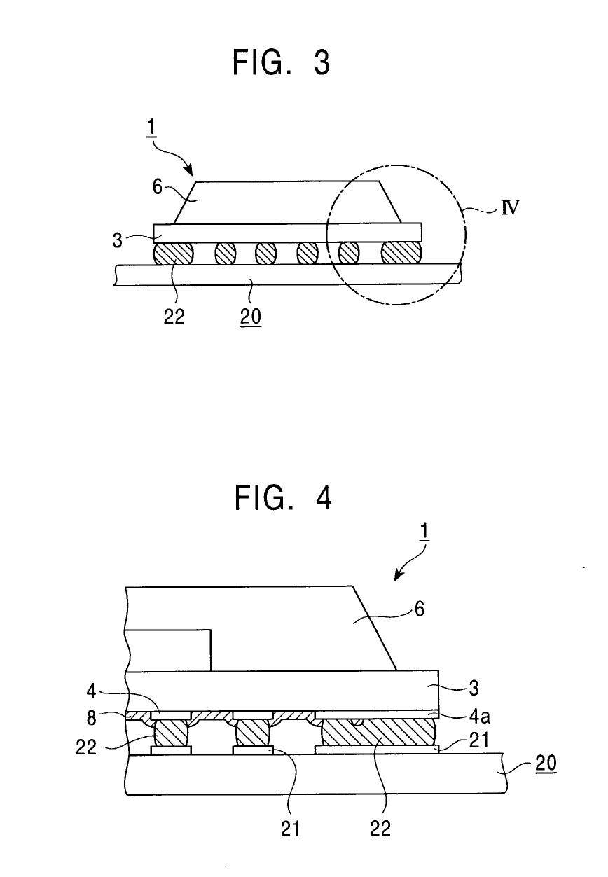

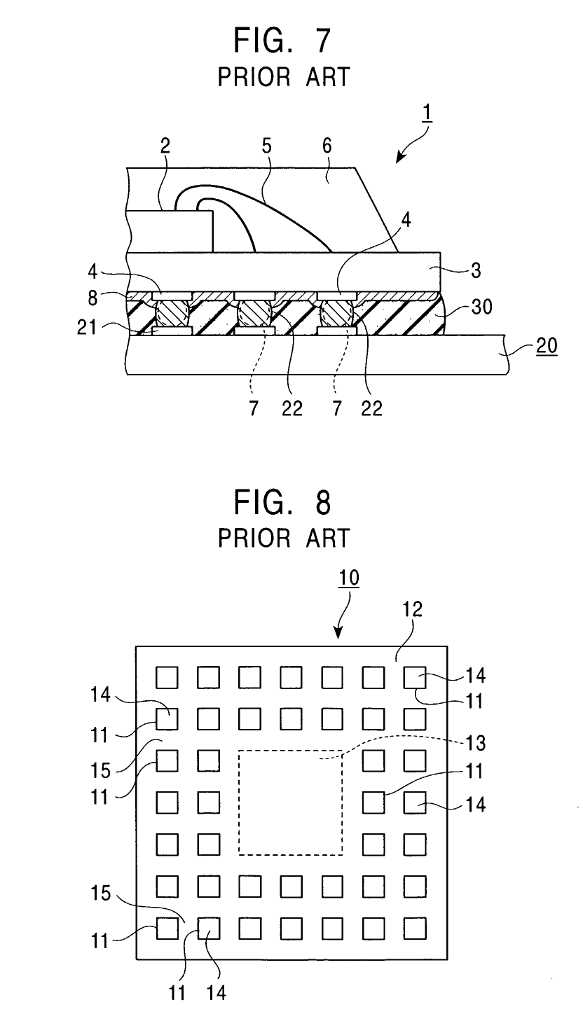

A description of embodiments of the present invention will now be given with reference to the drawings. FIG. 1 is a sectional view of the main portion of a BGA-type IC chip of an embodiment of the present invention. FIG. 2 is a schematic bottom view of the IC chip shown in FIG. 1. FIG. 3 is a schematic side view showing a state in which the IC chip is mounted to a mother board. FIG. 4 is an enlarged view of a portion within IV in FIG. 3. Corresponding parts to those shown in FIGS. 6 to 8 are given the same reference numerals.

A BGA-type IC chip 1 shown in FIGS. 1 to 4 includes an interposer substrate 3 having a semiconductor device 2 mounted thereto, a plurality of external connection lands 4 disposed in a grid-like arrangement on the bottom surface of the interposer substrate 3, a plurality of bonding wires 5 which electrically connect the semiconductor device 2 and each of the external connection lands 4, mold resin 6 which, on the interposer substrate 3, provides a seal for the semiconductor device 2 and each of the bonding wires 5, solder balls 7 which are adhered to the corresponding external connection lands 4 and which protrude downward from the bottom surface of the interposer substrate 3, and solder resist 8 which fills the area between adjacent external connection lands 4 at the bottom surface of the interposer substrate 3. Of the external connection lands 4, those that are positioned at four corners of the bottom surface of the interposer substrate 3 are formed as enlarged lands 4a that have larger areas than those positioned at other locations. As shown in FIG. 2, since these enlarged lands 4a are formed with sizes that allow them to be exposed at the outer sides of the corresponding solder balls 7, the amount of solder that adheres to the enlarged lands 4a can be made larger than the amount of solder that adheres to the other external connection lands 4 during the mounting process of the IC chip 1. Since, as shown in FIG. 1, a portion of the solder resist 8 is placed upon solder-ball-7-surrounding locations on the external connection lands 4 and the enlarged lands 4a, the positions of the solder balls 7 are restricted by the solder resist 8, so that the IC chip 1 has a structure in which displacements of the solder balls 7 do not easily occur. Although the solder balls 7 may be formed of solder alone, the solder balls 7 may be spherical resin or metal balls coated with solder.

When mounting the above-described IC chip 1 to a mother board 20, after printing cream solder onto connection lands 21 that are provided at the mother board 20 in an arrangement corresponding to that of the external connection lands, the solder balls 7 are placed on the cream solder and the resulting structure is heated at, for example, a reflow furnace in order to electrically and mechanically connect the external connection lands 4 and the corresponding connection lands 21 through molten cream solder 22 and the solder balls 7. Here, of the connection lands 21 on the mother board 20, those that are soldered to the enlarged lands 4a among the external connection lands 4 are previously formed with areas that are equal to the areas of the enlarged lands 4a (see FIG. 4). As a result, the amount of cream solder 22 that fills the area between the enlarged lands 4a and the opposing connection lands 21 is considerably larger than the amount of cream solder 22 at other locations, so that the enlarged lands 4a and the connection lands 21 are firmly connected together.

Accordingly, in the embodiment, enlarged lands 4a are provided at four corners of the bottom surface of the BGA-type IC chip 1 so that a large amount of cream solder 22 can adhere to the enlarged lands 4a. Therefore, the IC chip 1 is firmly soldered to the mother board 20 at the four corners thereof, so that, even if an external force is applied when they are twisted or are subjected to shock, the relative position between the IC chip 1 and the mother board 20 does not easily change. Consequently, the IC chip 1 and the mother board 20 are more reliably connected together at the portions where they are connected with solder (solder connection portions), so that it is not necessary to inject an insulating adhesive between the IC chip 1 and the mother board 20 to reinforce the portion between the IC chip 1 and the mother board 20. In other words, since it is not necessary to carry out the step of injecting an insulating adhesive, which is carried out when mounting a related BGA-type IC chip, the IC chip 1 can be efficiently mounted to the mother board 20 within a short time. In addition, since an insulating adhesive is not interposed between the IC chip 1 and the mother board 20, the possibility of the solder connection portions becoming damaged by changes in environmental temperature is reduced. Empty spaces whose distances to adjacent lands do not need to be narrowed down even when the external connection lands 4 are enlarged exist at the four corners of the bottom surface of the IC chip 1. Therefore, by using these empty spaces, it is possible to easily form enlarged lands 4a that do not induce short circuits.

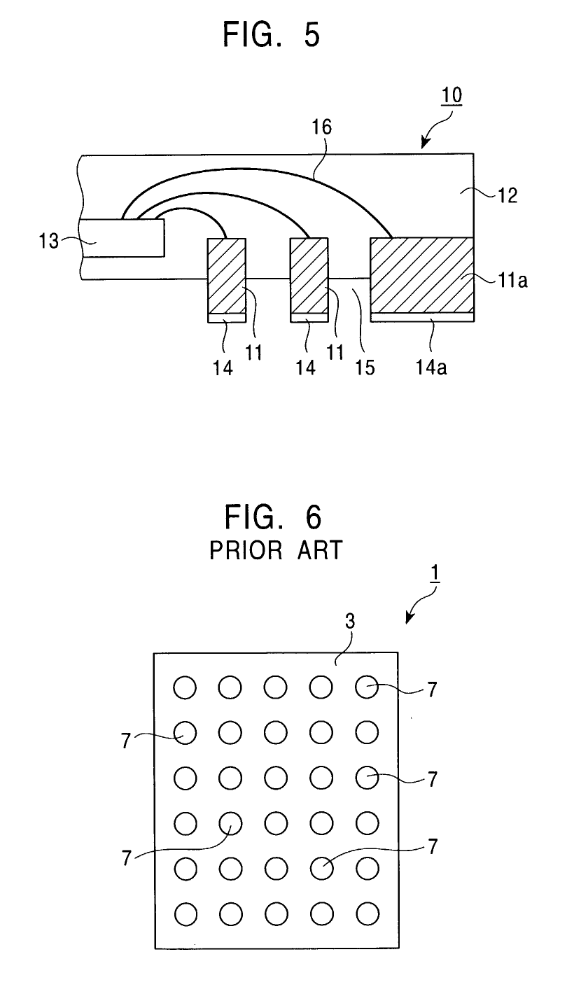

FIG. 5 is a sectional view of the main portion of a BCC-type IC chip of another embodiment of the present invention. An IC chip 10 shown in FIG. 5 includes a plurality of conductor terminals 11 which are disposed in a grid-like arrangement and which have external connection lands 14 formed on the bottom surfaces of the corresponding conductor terminals 11 by gold (Au) plating or the like, a semiconductor device 13, a plurality of bonding wires 16 that electrically connect the semiconductor device 13 and the conductor terminals 11, and mold resin 12 that provides a seal for the semiconductor device 13 and each of the bonding wires 16. Among the conductor terminals 11, thick conductor terminals 11a having diameters that are larger than the conductor terminals 11 that are disposed at locations other than the four corners of the bottom surface of the mold resin 12 are disposed at these four corners. The external connection lands 14 that are formed on the bottom surfaces of the corresponding thick conductor terminals 11a by plating are formed as enlarged lands 14a. Since each of the conductor terminals 11 protrudes downward from the mold resin 12, recesses 15 are formed between corresponding adjacent external connection lands 14.

Therefore, as in the IC chip 1 of the previous embodiment, in the IC chip 10, the amount of solder that adheres to the enlarged lands 14a can be made greater than the amount of solder that adheres to the other external connection lands 14 during the mounting process. In other words, this IC chip 10 can also be mounted with the four corners of its bottom surface firmly soldered to the mother board, so that it is not necessary to inject an insulating adhesive between the IC chip 10 and the mother board in order to reinforce the portion between IC chip 10 and the mother board.

The present invention is carried out in the forms described above, and provides the following advantages.

Since enlarged lands are provided at at least the four corners of the bottom surface of the IC chip, and a large amount of solder adheres to the enlarged lands, the four corners of the IC chip are firmly soldered to the mother board, so that, even if an external force is applied when, for example, the IC chip and the mother board are subjected to shock or are twisted, the relative position between them does not easily change. In addition, even if the portion between the IC chip and the mother board is not reinforced by injecting an insulating adhesive therebetween, it is possible to provide a highly reliable IC chip, to increase working efficiency during the mounting process of the IC chip, and to reduce the possibility of the solder connection portions becoming damaged due to changes in environmental temperature.

What is claimed is:

1. An integrated circuit chip including:
a semiconductor device and a bonding wire that are subjected to resin molding; and
a plurality of external connection lands, connected to the semiconductor device through the bonding wire, that are disposed at a bottom surface of the integrated circuit chip and that are soldered and mounted to a group of connection lands provided at a mother board;
wherein, of the plurality of external connection lands, at least the external connection lands that are disposed at four corners of the bottom surface of the integrated circuit chip are formed as enlarged lands that have areas that are larger than areas of the external connection lands that are disposed at other locations.

2. An integrated circuit chip according to claim 1, further including solder balls that are affixed to the corresponding external connection lands, wherein the enlarged lands are exposed at outer sides of the solder balls corresponding thereto.

3. An integrated circuit chip according to claim 2, wherein solder resist is provided between the plurality of external connection lands, with a portion of the solder resist being placed upon locations on the enlarged lands that surround the corresponding solder balls.

4. An integrated circuit chip according to claim 1, further including conductor terminals having the plurality of external connection lands formed at bottom surfaces of protruding portions of the conductor terminals by plating, and wherein, of the conductor terminals, the conductor terminals corresponding to the enlarged lands have diameters that are larger than diameters of the other conductor terminals.

5. A structure for mounting an integrated circuit chip, in which, when the integrated circuit chip is mounted to a mother board, a group of external connection lands and a group of connection lands are soldered with cream solder, with the integrated circuit chip comprising a semiconductor device and a bonding wire that are subjected to resin molding and the plurality of external connection lands, connected to the semiconductor device through the bonding wire, that are disposed at a bottom surface of the integrated circuit chip, and with the mother board having the group of connection lands disposed in an arrangement corresponding to that of the external connection lands; wherein, of the external connection lands of the integrated circuit chip, at least the external connection lands disposed at four corners of the bottom surface of the integrated circuit chip are formed as enlarged lands that have areas that are larger than areas of the external connection lands disposed at other locations, and, of the connection lands disposed at the mother board, the connection lands that are soldered to the enlarged lands are formed with areas that are equal to the areas of the enlarged lands, so that an amount of cream solder that adheres to the enlarged lands is greater than an amount of cream solder that adheres to the other external connection lands during the mounting process.
